(19) United States
(12) Patent Application Publication
(10) Pub. No.: US 2013/0076412 A1
(43) Pub. Date: Mar. 28, 2013

(54) CDR CIRCUIT

(71) Applicant: Junichiro SHIRAI, Kawasaki-Shi (JP)

(72) Inventor: Junichiro SHIRAI, Kawasaki-Shi (JP)

(73) Assignee: KABUSHIKI KAISHA TOSHIBA, Tokyo (JP)

(21) Appl. No.: 13/425,265

(22) Filed: Mar. 20, 2012

(30) Foreign Application Priority Data
Sep. 26, 2011 (JP) 2011-208873

(51) Int. Cl. H03L 7/06

(52) U.S. Cl. 327/156

(57) ABSTRACT

When the comparison result signal indicates that the amplitude of the received data signal in synchronization with the data sampling clock signal is larger than the reference voltage, the lock detecting circuit determines that a lock condition occurs in which the data sampling clock signal locks the phase of the data of the received data signal, and outputs a lock flag signal.

### CROSS-REFERENCE TO RELATED APPLICATION

This application is based upon and claims the benefit of priority from the prior Japanese Patent Application No. 2011-208873, filed on Sep. 26, 2011, the entire contents of which are incorporated herein by reference.

### BACKGROUND

1. Field

Embodiments described herein relate generally to a Clock Data Recovery (CDR) circuit.

2. Background Art

CDR circuits are used for fast serial data transmission.

### BRIEF DESCRIPTION OF THE DRAWINGS

FIG. 1 is a diagram showing a received data signal including a deterministic jitter, a data sampling clock signal and an edge sampling clock signal for sampling that are in an ideal phase relationship;

FIG. 2 is a diagram showing the received data signal including a deterministic jitter, the data sampling clock signal and the edge sampling clock signal for sampling that are in a false lock condition;

FIG. 3 is a diagram showing an example of a configuration of a CDR circuit 100 according to a first embodiment;

FIG. 4 is a diagram showing a relationship between a received data signal including a deterministic jitter and a reference voltage in an ideal phase condition;

FIG. 5 is a diagram showing a relationship between a received data signal including a deterministic jitter and a reference voltage in a false lock condition;

FIG. 6 is a diagram showing an example of a configuration of a CDR circuit 200 according to the second embodiment;

FIG. 7 is a diagram showing a relationship between the desired value of the amplitude of the output signal (received data signal) of the equalizer and the reference voltage;

FIG. 8 is a diagram showing an example of a configuration of a CDR circuit 300 according to the third embodiment; and

FIG. 9 is a diagram showing a relationship between the maximum value of the amplitude of the output signal (received data signal) of the equalizer EQ and the reference voltage.

### DETAILED DESCRIPTION

A CDR circuit according to an embodiment includes an equalizer that amplifies a serial data signal and outputs a received data signal. The CDR circuit includes an amplitude detecting circuit that detects a maximum value of an amplitude of the received data signal. The CDR circuit includes a reference voltage generating circuit that generates a reference voltage set at a value smaller than the maximum value of the amplitude of the received data signal detected by the amplitude detecting circuit. The CDR circuit includes a data sampling circuit that samples the received data signal and generates a sampled data signal in synchronization with a data sampling clock signal that is used to sample data of the received data signal. The CDR circuit includes an edge sampling circuit that samples the received data signal and generates a sampled edge signal in synchronization with an edge sampling clock signal that is out of phase with the data sampling clock signal. The CDR circuit includes an amplitude comparing circuit that compares the amplitude of the received data signal with the reference voltage and outputs a comparison result signal obtained by the comparison in synchronization with the data sampling clock signal. The CDR circuit includes a phase shifting circuit that adjusts a phase of the data sampling clock signal based on the comparison result signal, the sampled data signal and the sampled edge signal. The CDR circuit includes a lock detecting circuit that detects a phase relationship between the received data signal and the data sampling clock signal based on the comparison result signal and the sampled data signal.

when the comparison result signal indicates that the amplitude of the received data signal in synchronization with the data sampling clock signal is larger than the reference voltage, the lock detecting circuit determines that a lock condition occurs in which the data sampling clock signal locks the phase of the data of the received data signal, and outputs a lock flag signal.

A CDR circuit adjusts the phase of the data sampling clock signal CLK for sampling data of a received data signal RX_P/N.

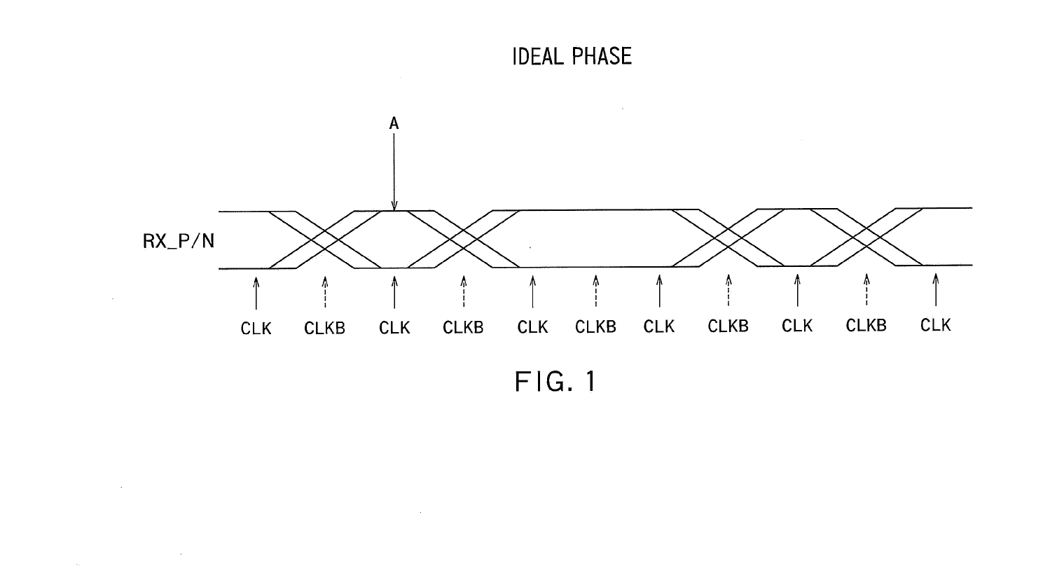

FIG. 1 is a diagram showing a received data signal including a deterministic jitter, a data sampling clock signal and an edge sampling clock signal for sampling that are in an ideal phase relationship.

As shown in FIG. 1, a data sampling clock signal CLK locks the phase of the data of the received data signal RX_P/N. And an edge sampling clock signal CLKB locks the phase of an edge of the received data signal.

As shown, in the ideal phase relationship, the data sampling clock signal CLK occurs around the center of the pattern of the received data signal RX_P/N (as shown by the arrow A in FIG. 1).

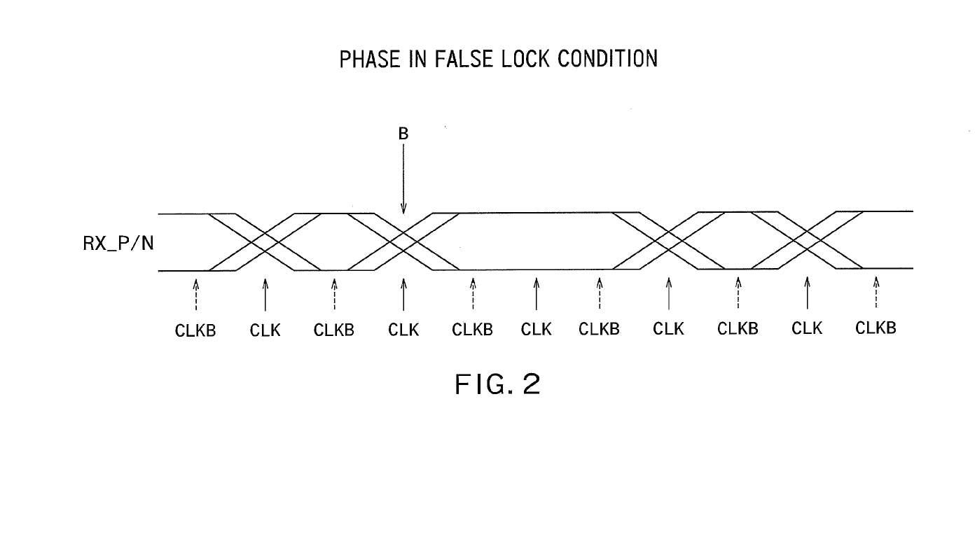

FIG. 2 is a diagram showing the received data signal including a deterministic jitter, the data sampling clock signal and the edge sampling clock signal for sampling that are in a false lock condition.

As shown in FIG. 2, the data sampling clock signal CLK locks the phase of the edge of the received data signal RX_P/N (as shown by the arrow B in FIG. 2). And the edge sampling clock signal CLKB locks the phase of the data of the received data signal.

That is, in the condition shown in FIG. 2, the data sampling clock signal CLK does not lock the phase of the data of the received data signal RX_P/N (an unlock condition).

The CDR circuit incorporating a binary phase detector or the like has an advantage that it has a simple circuit configuration. However, such a CDR circuit can only obtain phase information as to whether the phase is delayed or advanced that does not include the magnitude of a phase difference.

As a result, if the received data signal includes many deterministic jitters (Dj) such as Inter-Symbol Interference (ISI), a condition in which a false phase is locked rather than a phase originally intended to be locked (a condition in which sampling with the data sampling clock occurs at a time during transition of the received data signal) can occur. In the following, this condition will be referred to as a false lock condition. In the false lock condition, the data can be read out with the edge sampling clock, with which the edge would otherwise be sampled.

Thus, there is a problem that the CDR circuit described above may determine that it is in a normal lock condition even when the edge of the received data signal RX_P/N is sampled with the data sampling clock signal CLK.

To solve the problem, CDR circuits capable of properly detecting whether the circuits are in the lock condition or not and outputting the detection result will be proposed in the following description of embodiments.

In the following, the embodiments will be described with reference to the drawings.

### First Embodiment

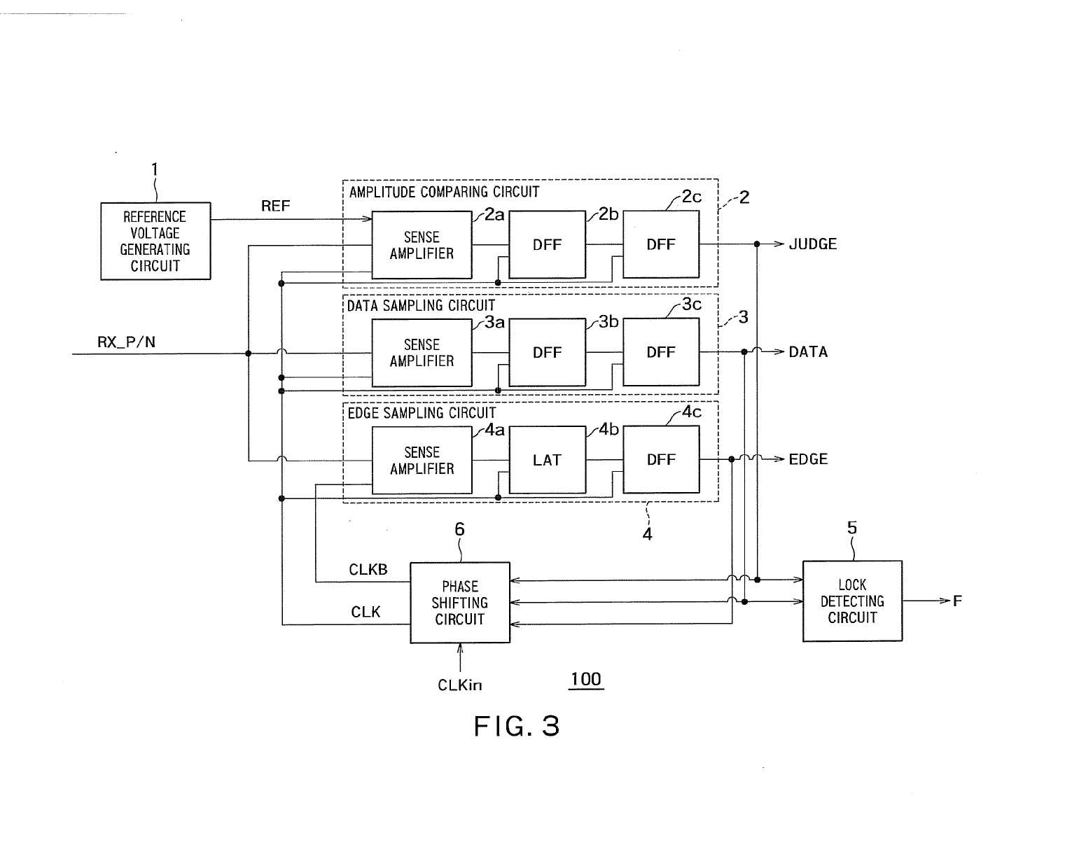

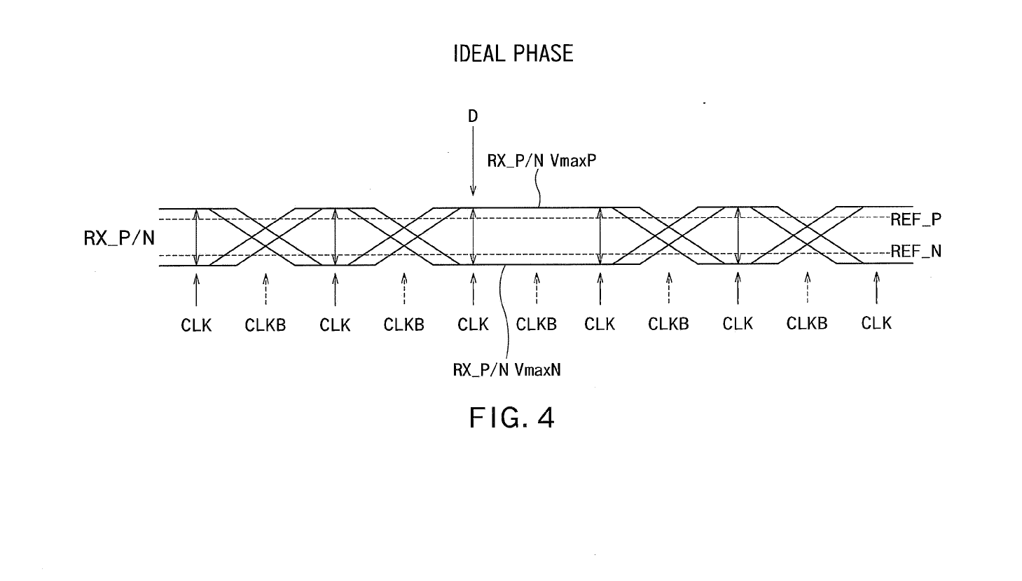

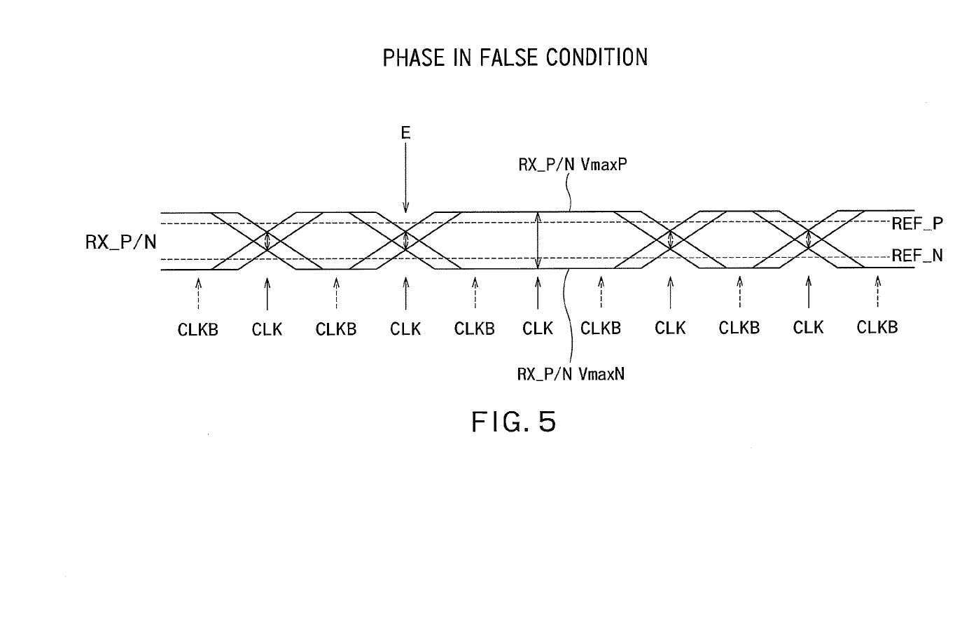

FIG. 3 is a diagram showing an example of a configuration of a CDR circuit 100 according to a first embodiment. FIG. 4 is a diagram showing a relationship between a received data signal including a deterministic jitter and a reference voltage in an ideal phase condition. FIG. 5 is a diagram showing a relationship between a received data signal including a deterministic jitter and a reference voltage in a false lock condition.

As shown in FIG. 3, the CDR circuit 100 is configured to output the result of sampling of a received data signal (fast serial data) RX_P/N with a clock signal. The CDR circuit 100 is used for Peripheral Component Interconnect (PCI) Express, Serial Advanced Technology Attachment (SATA), or USB 3.0 (SuperSpeed USB).

The CDR circuit 100 includes a reference voltage generating circuit 1, an amplitude comparing circuit 2, a data sampling circuit 3, an edge sampling circuit 4, a lock detecting circuit 5, and a phase shifting circuit 6.

The reference voltage generating circuit 1 is configured to generate and output a reference voltage “REF”. The reference voltage generating circuit 1 sets the reference voltage “REF” (“REF_P”, “REF_N”) at a value smaller than a maximum value (“RX_P/N VmaxP”, “RX_P/N VmaxN”) of the amplitude of the received data signal RX_P/N, for example (FIGS. 4 and 5). In addition, the reference voltage generating circuit 1 sets the reference voltage “REF” (“REF_P”, “REF_N”) at a value larger than the value of the amplitude of the edge of the received data signal RX_P/N, for example (FIGS. 4 and 5).

If the polarity of the received data signal RX_P/N is negative with respect to the point at which the amplitude of the received data signal RX_P/N is zero, the value of the amplitude of the received data signal RX_P/N and the value of the reference voltage “REF” are represented by absolute values (the same holds true for the following description).

The data sampling circuit 3 is configured to sample the received data signal RX_P/N and generate a sampled data signal DATA in synchronization with the data sampling clock signal CLK. As described above, the data sampling clock signal CLK is a signal used for sampling the data of the received data signal RX_P/N.

As shown in FIG. 3, the data sampling circuit 3 includes a sense amplifier 3a and two flip-flops 3b and 3c, for example.

The sense amplifier 3a outputs a signal that is produced by amplifying the voltage variations of the received data signal RX_P/N in synchronization with the data sampling clock signal CLK.

The signal output from the sense amplifier 3a is input to the flip-flop 3b. The flip-flop 3b holds and outputs the input signal in synchronization with the data sampling clock signal CLK.

The signal output from the flip-flop 3b is input to the flip-flop 3c. The flip-flop 3c holds the input signal and outputs the sampled data signal DATA described above in synchronization with the data sampling clock signal CLK.

The amplitude comparing circuit 2 is configured to compare the amplitude of the received data signal RX_P/N with the reference voltage “REF” and output a comparison result signal JUDGE obtained by the comparison in synchronization with the data sampling clock signal CLK.

As shown in FIG. 3, the amplitude comparing circuit 2 includes a sense amplifier 2a and two flip-flops 2b and 2c, for example.

The sense amplifier 2a compares the amplitude of the received data signal RX_P/N with the reference voltage “REF” in synchronization with the data sampling clock signal CLK and outputs a signal determined by the comparison result.

The signal output from the sense amplifier 2a is input to the flip-flop 2b. The flip-flop 2b holds and outputs the input signal in synchronization with the data sampling clock signal CLK.

The signal output from the flip-flop 2b is input to the flip-flop 2c. The flip-flop 2c holds the input signal and outputs the comparison result signal JUDGE described above in synchronization with the data sampling clock signal CLK.

Therefore, the comparison result signal JUDGE and the sampled data signal DATA are in phase with each other. The edge sampling circuit 4 is configured to sample the received data signal RX_P/N and generate a sampled edge signal EDGE in synchronization with the edge sampling clock signal CLKB.

The edge sampling clock signal CLKB is a signal used for sampling the edge of the received data signal RX_P/N and is out of phase with the data sampling clock signal CLK (by a half period, for example).

As shown in FIG. 3, the edge sampling circuit 4 includes a sense amplifier 4a, a latch circuit 4b and flip-flop 4c, for example.

The sense amplifier 4a outputs a signal that is produced by amplifying the voltage variations of the received data signal RX_P/N in synchronization with the edge sampling clock signal CLKB.

The signal output from the sense amplifier 4a is input to the latch circuit 4b. The latch circuit 4b holds and outputs the input signal in synchronization with the data sampling clock signal CLK.

The signal output from the latch circuit 4b is input to the flip-flop 4c. The flip-flop 4c holds the input signal and outputs the sampled edge signal EDGE described above in synchronization with the data sampling clock signal CLK.

Therefore, the sampled edge signal EDGE is out of phase with the comparison result signal JUDGE and the sampled data signal DATA by a half period.

The phase shifting circuit 6 is configured to generate, from an external clock CLKin, the data sampling clock signal CLK with which the data of the received data signal RX_P/N is to be sampled and the edge sampling clock signal CLKB with which the edge of the received data signal RX_P/N is to be sampled.

Based on the sampled data signal DATA, the sampled edge signal EDGE and the comparison result signal JUDGE, the phase shifting circuit 6 determines whether the phase of the data sampling clock signal CLK is delayed or advanced from the phase of the data of the received data signal RX_P/N. The phase shifting circuit 6 can make the determination as to the phase of the data of the received data signal RX_P/N even if the comparison result signal JUDGE is not input to the phase shifting circuit 6.

Then, based on the result of the determination, the phase shifting circuit 6 adjusts the phases of the data sampling clock signal CLK and the edge sampling clock signal CLKB so that the data sampling clock signal CLK locks the phase of the data of the received data signal RX_P/N (or the edge sampling clock signal CLKB locks the edge of the received data signal RX_P/N).

The lock detecting circuit 5 is configured to detect the phase relationship between the received data signal RX_P/N and the data sampling clock signal CLK (whether a lock condition has occurred or not) based on the comparison result signal JUDGE and the sampled data signal DATA and output a signal determined by the detection result.

For example, when the comparison result signal JUDGE indicates that the amplitude of the received data signal RX_P/N is larger than the reference voltage “REF” (as shown by the arrow D in FIG. 4), the lock detecting circuit 5 determines that a lock condition occurs in which the data sampling clock signal CLK locks the phase of the data of the received data signal RX_P/N, and outputs a lock flag signal F.

On the other hand, when the comparison result signal JUDGE indicates that the amplitude of the received data signal RX_P/N is smaller than the reference voltage “REF” (as shown by the arrow E in FIG. 5), the lock detecting circuit 5 determines that an unlock condition occurs in which the data sampling clock signal CLK does not lock the phase of the data of the received data signal RX_P/N, and does not output the lock flag signal F. In other words, in this case, the lock detecting circuit 5 outputs an unlock flag signal (not shown) that indicates the unlock condition.

More preferably, the lock detecting circuit 5 outputs the lock flag signal F based on the comparison result signal JUDGE and the sampled data signal DATA. For example, when the comparison result signal JUDGE indicates that the amplitude of the received data signal RX_P/N is larger than the reference voltage “REF”, and the sampled data signal DATA matches with a preset data pattern, the lock detecting circuit 5 outputs the lock flag signal F.

In this way, the reliability of the lock flag signal F can be improved.

The data pattern is a data pattern obtained by sampling the data of the received data signal RX_P/N in a normal lock condition. In particular, the data pattern is a data pattern referred to as COMMA or K28.5, for example. The data pattern is previously stored in the lock detecting circuit 5.

As described above, in the unlock condition, sampling with the data sampling clock signal CLK occurs at a time during transition of the received data signal RX_P/N.

Based on the lock flag signal F, a signal processing system (not shown) can recognize that the sampled data signal DATA is sampled in the lock condition, for example.

On the other hand, if the lock flag signal F is not output, the signal processing system can recognize that the sampled data signal DATA is sampled in the unlock condition.

As described above, the signal processing system can determine the validity of the sampled data signal DATA based on the lock flag signal F.

In particular, as described above, the lock detecting circuit 5 more preferably outputs the lock flag signal F based on the comparison result signal JUDGE and the sampled data signal DATA.

In this case, the reliability of the lock flag signal F is improved, and therefore, the signal processing system can more accurately determine the validity of the sampled data signal DATA based on the lock flag signal F.

As described above, the CDR circuit according to the first embodiment can more properly detect whether the lock condition has occurred or not and output the detection result.

### Second Embodiment

In the above first embodiment, a case where the reference voltage generating circuit generates a reference voltage having a preset value has been described.

In a second embodiment, a case where the reference voltage generating circuit sets a reference voltage at a value smaller than a desired value of the amplitude of an output signal (received data signal) set in an equalizer will be described.

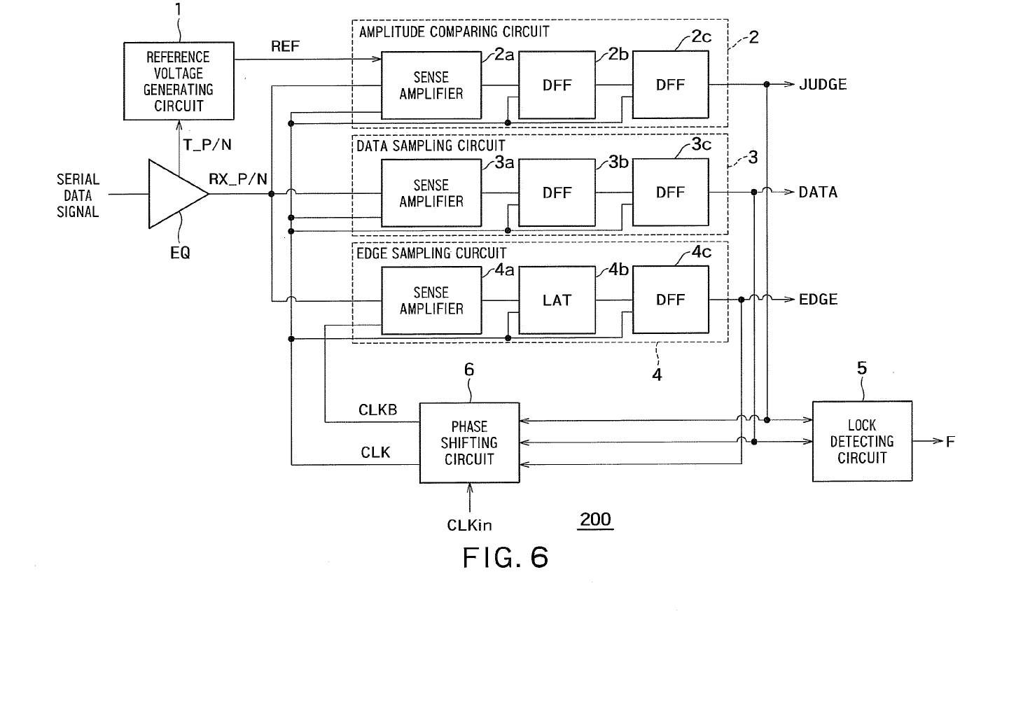

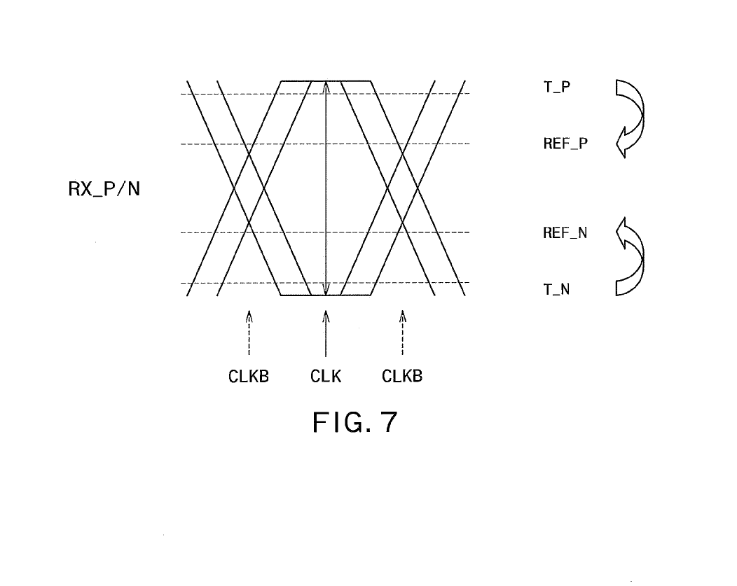

FIG. 6 is a diagram showing an example of a configuration of a CDR circuit 200 according to the second embodiment. FIG. 7 is a diagram showing a relationship between the desired value of the amplitude of the output signal (received data signal) of the equalizer and the reference voltage. In FIG. 6, the same reference numerals as those in FIG. 3 denote the same components as those in the first embodiment.

As shown in FIG. 6, the CDR circuit 200 includes the reference voltage generating circuit 1, the amplitude comparing circuit 2, the data sampling circuit 3, the edge sampling circuit 4, the lock detecting circuit 5, and the phase shifting circuit 6, as in the first embodiment.

The second embodiment differs from the first embodiment in that an equalizer EQ amplifies a serial data signal and outputs the received data signal RX_P/N.

Therefore, the amplitude of the received data signal RX_P/N varies with the desired value T_P/N of the amplitude of the received data signal RX_P/N set in the equalizer EQ.

The reference voltage generating circuit 1 is configured to set the reference voltage “REF” at a value smaller than the desired value T_P/N of the amplitude of the received data signal RX_P/N set in the equalizer EQ (FIG. 7).

The amplitude comparing circuit 2 compares the amplitude of the received data signal RX_P/N with the reference voltage “REF” in synchronization with the data sampling clock signal CLK and outputs the comparison result signal JUDGE obtained by the comparison, as in the first embodiment.

The lock detecting circuit 5 detects the phase relationship between the received data signal RX_P/N and the data sampling clock signal CLK (whether a lock condition has occurred or not) based on the comparison result signal JUDGE and the sampled data signal DATA and outputs the lock flag signal F according to the detection result.

As described above, the CDR circuit 200 can properly generate the comparison result signal JUDGE and output the lock flag signal F based on the comparison result signal JUDGE regardless of the desired value of the amplitude set in the equalizer EQ.

The remainder of the configuration and function of the CDR circuit 200 according to the second embodiment is the same as that of the CDR circuit 100 according to the first embodiment.

That is, the CDR circuit according to the second embodiment can more properly detect whether the lock condition has occurred or not and output the detection result, as in the first embodiment.

### Third Embodiment

In a third embodiment, a case where the reference voltage generating circuit sets a reference voltage at a value smaller than a maximum value of the amplitude of an output signal (received data signal) of the equalizer will be described.

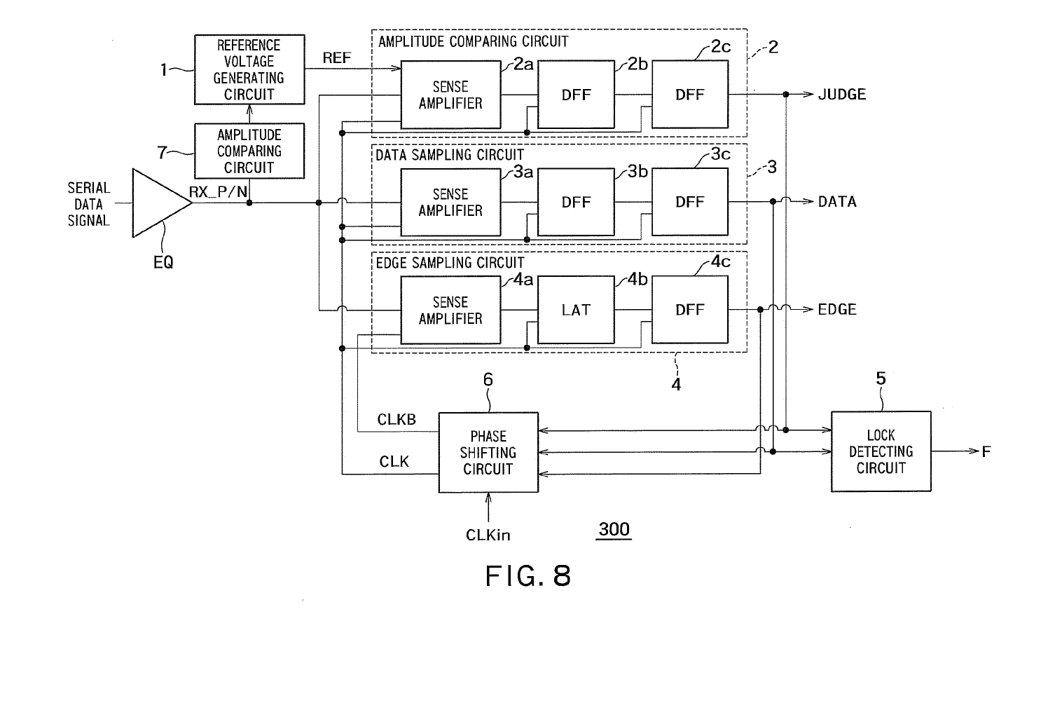

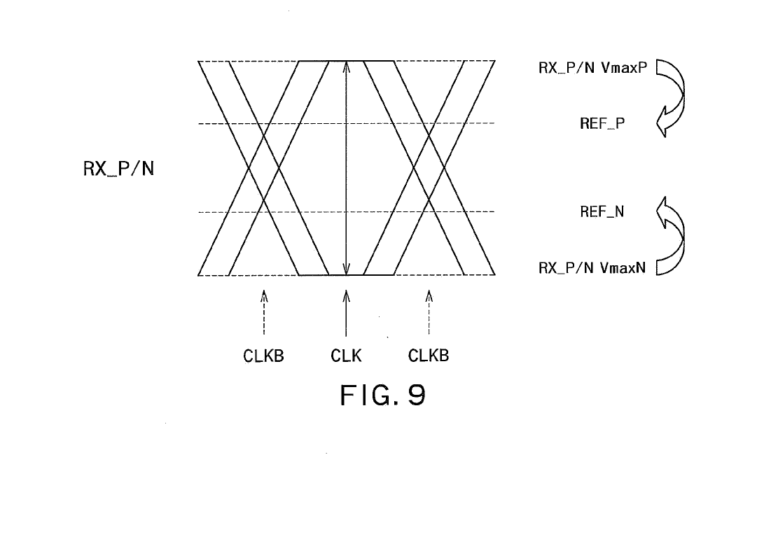

FIG. 8 is a diagram showing an example of a configuration of a CDR circuit 300 according to the third embodiment. FIG. 9 is a diagram showing a relationship between the maximum value of the amplitude of the output signal (received data signal) of the equalizer EQ and the reference voltage. In FIG. 8, the same reference numerals as those in FIG. 6 denote the same components as those in the second embodiment.

As shown in FIG. 8, the CDR circuit 300 includes the reference voltage generating circuit 1, the amplitude comparing circuit 2, the data sampling circuit 3, the edge sampling circuit 4, the lock detecting circuit 5, and the phase shifting circuit 6 as in the second embodiment, and further includes an amplitude detecting circuit 7.

As in the second embodiment, the equalizer EQ amplifies the serial data signal and outputs the received data signal RX_P/N.

Therefore, the amplitude of the received data signal RX_P/N varies with the desired value T_P/N of the amplitude of the received data signal RX_P/N set in the equalizer EQ, as in the second embodiment.

The amplitude detecting circuit 7 is configured to detect the maximum value of the amplitude of the received data signal RX_P/N output from the equalizer EQ.

The reference voltage generating circuit 1 is configured to set the reference voltage “REF” at a value smaller than the maximum value of the amplitude of the received data signal RX_P/N detected by the amplitude detecting circuit 7 (FIG. 9).

The amplitude comparing circuit 2 compares the amplitude of the received data signal RX_P/N with the reference voltage “REF” in synchronization with the data sampling clock signal CLK and outputs the comparison result signal JUDGE obtained by the comparison, as in the first embodiment.

The lock detecting circuit 5 detects the phase relationship between the received data signal RX_P/N and the data sampling clock signal CLK (whether a lock condition has occurred or not) based on the comparison result signal JUDGE and the sampled data signal DATA and outputs the lock flag signal F according to the detection result.

As described above, the CDR circuit 300 can properly generate the comparison result signal JUDGE and output the lock flag signal F based on the comparison result signal JUDGE regardless of the desired value of the amplitude set in the equalizer EQ.

The remainder of the configuration and function of the CDR circuit 300 according to the third embodiment is the same as that of the CDR circuit 100 according to the first embodiment.

That is, the CDR circuit according to the third embodiment can more properly detect whether the lock condition has occurred or not and output the detection result, as in the first embodiment.

Although cases where the received data signal is a differential signal have been described in the above embodiments, the above description holds true for cases where the received data signal is a single-phase signal.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A CDR circuit, comprising:
an equalizer that amplifies a serial data signal and outputs a received data signal;
an amplitude detecting circuit that detects a maximum value of an amplitude of the received data signal;
a reference voltage generating circuit that generates a reference voltage set at a value smaller than the maximum value of the amplitude of the received data signal detected by the amplitude detecting circuit;
a data sampling circuit that samples the received data signal and generates a sampled data signal in synchronization with a data sampling clock signal that is used to sample data of the received data signal;
an edge sampling circuit that samples the received data signal and generates a sampled edge signal in synchronization with an edge sampling clock signal that is out of phase with the data sampling clock signal;
an amplitude comparing circuit that compares the amplitude of the received data signal with the reference voltage and outputs a comparison result signal obtained by the comparison in synchronization with the data sampling clock signal;
a phase shifting circuit that adjusts a phase of the data sampling clock signal based on the comparison result signal, the sampled data signal and the sampled edge signal; and
a lock detecting circuit that detects a phase relationship between the received data signal and the data sampling clock signal based on the comparison result signal and the sampled data signal,
wherein, when the comparison result signal indicates that the amplitude of the received data signal in synchronization with the data sampling clock signal is larger than the reference voltage, the lock detecting circuit determines that a lock condition occurs in which the data sampling clock signal locks the phase of the data of the received data signal, and outputs a lock flag signal.

2. The CDR circuit according to claim 1, wherein, when the comparison result signal indicates that the amplitude of the received data signal is smaller than the reference voltage, the lock detecting circuit determines that an unlock condition occurs in which the data sampling clock signal does not lock the phase of the data of the received data signal, and does not output the lock flag signal.

3. The CDR circuit according to claim 1, wherein the lock detecting circuit outputs the lock flag signal, when the sampled data signal matches with a preset data pattern and the comparison result signal indicates that the amplitude of the received data signal is larger than the reference voltage.

4. The CDR circuit according to claim 1, wherein the edge sampling clock signal is out of phase with the data sampling clock signal by a half period.

5. The CDR circuit according to claim 1, wherein the CDR circuit is used for Peripheral Component Interconnect (PCI) Express, Serial Advanced Technology Attachment (SATA), or USB 3.0 (SuperSpeed USB).

6. The CDR circuit according to claim 1, wherein the reference voltage generating circuit sets the reference voltage at a value larger than the value of the amplitude of an edge of the received data signal.

7. A CDR circuit, comprising:
a reference voltage generating circuit that generates a reference voltage;
a data sampling circuit that samples a received data signal and generates a sampled data signal in synchronization with a data sampling clock signal that is used to sample data of the received data signal;
an edge sampling circuit that samples the received data signal and generates a sampled edge signal in synchronization with an edge sampling clock signal that is out of phase with the data sampling clock signal;
an amplitude comparing circuit that compares the amplitude of the received data signal with the reference voltage and outputs a comparison result signal obtained by the comparison in synchronization with the data sampling clock signal;
a phase shifting circuit that adjusts a phase of the data sampling clock signal based on the sampled data signal and the sampled edge signal; and
a lock detecting circuit that detects a phase relationship between the received data signal and the data sampling clock signal based on the comparison result signal and the sampled data signal,
wherein, when the comparison result signal indicates that the amplitude of the received data signal in synchronization with the data sampling clock signal is larger than the reference voltage, the lock detecting circuit determines that a lock condition occurs in which the data sampling clock signal locks the phase of the data of the received data signal, and outputs a lock flag signal.

8. The CDR circuit according to claim 7, wherein the reference voltage generating circuit sets the reference voltage at a value smaller than a maximum value of the amplitude of the received data signal.

9. The CDR circuit according to claim 7, wherein the phase shifting circuit adjusts the phase of the data sampling clock signal based on the sampled data signal and the comparison result signal.

10. The CDR circuit according to claim 7, wherein the lock detecting circuit outputs the lock flag signal, when the sampled data signal matches with a preset data pattern and the comparison result signal indicates that the amplitude of the received data signal is larger than the reference voltage.

11. The CDR circuit according to claim 7, wherein the edge sampling clock signal is out of phase with the data sampling clock signal by a half period.

12. The CDR circuit according to claim 7, wherein the CDR circuit is used for Peripheral Component Interconnect (PCI) Express, Serial Advanced Technology Attachment (SATA), or USB 3.0 (SuperSpeed USB).

13. The CDR circuit according to claim 7, wherein the reference voltage generating circuit sets the reference voltage at a value larger than the value of the amplitude of an edge of the received data signal.

14. A CDR circuit, comprising:
an equalizer that amplifies a serial data signal and outputs a received data signal;
a reference voltage generating circuit that generates a reference voltage set at a value smaller than a desired value of the amplitude of the received data signal detected by the amplitude detecting circuit;
a data sampling circuit that samples the received data signal and generates a sampled data signal in synchronization with a data sampling clock signal that is used to sample data of the received data signal;
an edge sampling circuit that samples the received data signal and generates a sampled edge signal in synchronization with an edge sampling clock signal that is out of phase with the data sampling clock signal;
an amplitude comparing circuit that compares the amplitude of the received data signal with the reference voltage and outputs a comparison result signal obtained by the comparison in synchronization with the data sampling clock signal;
a phase shifting circuit that adjusts a phase of the data sampling clock signal based on the sampled data signal and the sampled edge signal; and
a lock detecting circuit that detects a phase relationship between the received data signal and the data sampling clock signal based on the comparison result signal and the sampled data signal,
wherein, when the comparison result signal indicates that the amplitude of the received data signal in synchronization with the data sampling clock signal is larger than the reference voltage, the lock detecting circuit determines that a lock condition occurs in which the data sampling clock signal locks the phase of the data of the received data signal, and outputs a lock flag signal.

15. The CDR circuit according to claim 14, wherein the lock detecting circuit outputs the lock flag signal, when the sampled data signal matches with a preset data pattern and the comparison result signal indicates that the amplitude of the received data signal is larger than the reference voltage.

16. The CDR circuit according to claim 14, wherein the edge sampling clock signal is out of phase with the data sampling clock signal by a half period.

17. The CDR circuit according to claim 14, wherein the CDR circuit is used for Peripheral Component Interconnect (PCI) Express, Serial Advanced Technology Attachment (SATA), or USB 3.0 (SuperSpeed USB).

18. The CDR circuit according to claim 14, wherein the reference voltage generating circuit sets the reference voltage at a value larger than the value of the amplitude of an edge of the received data signal.
